(19) United States
(12) Patent Application Publication
(10) Pub. No.: US 2025/0357343 A1
(43) Pub. Date: Nov. 20, 2025

(54) CELL HEIGHT REDUCTION USING A DEEP POWER RAIL PROCESS

(71) Applicant: QUALCOMM Incorporated, San Diego, CA (US)

(72) Inventors: Yan SUN, San Diego, CA (US); Shreesh NARASIMHA, Charlotte, NC (US)

(21) Appl. No.: 18/668,926

(22) Filed: May 20, 2024

(51) Int. Cl. H01L 23/528; H01L 21/768; H01L 21/8234; H01L 23/522; H01L 27/088; H01L 29/06; H01L 29/423; H01L 29/66; H01L 29/775; H01L 29/78; H01L 29/786

(52) U.S. Cl. CPC H01L 23/5286; H01L 21/76831; H01L 21/76877; H01L 23/5226; H10D 30/014; H10D 30/024; H10D 30/43; H10D 30/62; H10D 30/6735; H10D 30/6757; H10D 62/121; H10D 84/0149; H10D 84/038; H10D 84/834

(57) ABSTRACT

A chip includes a first epitaxial (epi) layer, a first contact disposed on the first epi layer, and a rail coupled to the first contact, wherein the rail has a first height in a first direction. The chip also includes a second epi layer, a second contact disposed on the second epi layer, and a signal line, wherein the signal line has a second height in the first direction, and the first height is greater than the second height. The chip also includes a via disposed between the second contact and the signal line in the first direction.

### BACKGROUND

### Field

Aspects of the present disclosure relate generally to chip layout, and more particularly, to cell height reduction using a deep power rail process.

### Background

A chip includes many transistors for performing various functions on the chip. The transistors may be implemented using fin field effect transistors (FinFETs), gate-all-around field effect transistors (GAAFETs), and/or other types of transistors. With advances in semiconductor technology, there is a continuous demand to scale down the dimensions of the transistors and the spacing between the transistors to fit a larger number of transistors on the chip.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first epitaxial (epi) layer, a first contact disposed on the first epi layer, and a rail coupled to the first contact, wherein the rail has a first height in a first direction. The chip also includes a second epi layer, a second contact disposed on the second epi layer, and a signal line, wherein the signal line has a second height in the first direction, and the first height is greater than the second height. The chip also includes a via disposed between the second contact and the signal line in the first direction.

A second aspect relates to a chip. The chip includes a first rail and a second rail, wherein each of the first rail and the second rail has a first height in a first direction. The chip also includes a first epitaxial (epi) layer, and a first contact disposed on the first epi layer, wherein the first rail is coupled to the first contact. The chip also includes signal lines between the first rail and the second rail in a second direction perpendicular to the first direction, wherein each of the signal lines has a second height in the first direction, and the first height is greater than the second height. The chip also includes a second epi layer, a second contact disposed on the second epi layer, and a via disposed between the second contact and one of the signal lines in the first direction.

A third aspect relates to a method for fabricating a chip. The chip includes a first epitaxial (epi) layer, a first contact disposed on the first epi layer, a second epi layer, a second contact disposed on the second epi layer, a via disposed on the second contact, and a dielectric layer over the first contact and the via. The method includes etching a first trench in the dielectric layer to a depth of the first contact, etching a second trench in the dielectric layer to a depth of the via, filling the first trench with a first metal to form a rail, and filling the second trench with a second metal to form a signal line.

A fourth aspect relates to a chip. The chip includes a first rail and a second rail, wherein each of the first rail and the second rail has a first height in a first direction. The chip also includes a first epitaxial (epi) layer, a first contact disposed on the first epi layer, wherein the first rail is coupled to the first contact, a second epi layer, and a second contact disposed on the second epi layer, wherein the second rail is coupled to the second contact. The chip also includes signal lines between the first rail and the second rail in a second direction perpendicular to the first direction, wherein each of the signal lines has a second height in the first direction, and the first height is greater than the second height. The chip also includes a third epi layer, a third contact disposed on the third epi layer, and a via disposed between the third contact and one of the signal lines in the first direction.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a FinFET according to certain aspects of the present disclosure.

FIG. 1C shows a perspective view of the transistor implemented with a gate-all-around FET according to certain aspects of the present disclosure.

FIG. 2A shows a top view of an example of a cell including a first transistor and a second transistor according to certain aspects of the present disclosure.

FIG. 2B shows a top view of an example of metal tracks including rails and signal lines for providing power and signal routing for the cell according to certain aspects of the present disclosure.

FIG. 2C shows a top view of an example of contacts disposed on epitaxial (epi) layers in the cell according to certain aspects of the present disclosure.

FIG. 2D shows an example in which a first one of the contacts is coupled to a rail and a second one of the contacts is coupled to a signal line according to certain aspects of the present disclosure.

FIG. 2E shows a cross-sectional view of the cell taken along a cross-section line in FIG. 2D according to certain aspects of the present disclosure.

FIG. 3A shows a top view of an example of metal tracks including rails and signal lines in which the rails of FIG. 3A have smaller widths than the rails of FIG. 2A according to certain aspects of the present disclosure.

FIG. 3B shows a cross-sectional view of the metal tracks of FIG. 3A according to certain aspects of the present disclosure.

FIG. 4A shows an example in which one of the rails of FIG. 3A is coupled to a first contact in the cell and one of the signal lines of FIG. 3A is coupled to a second contact according to certain aspects of the present disclosure.

FIG. 4B shows a cross-sectional view of the cell taken along a cross-section line in FIG. 4A according to certain aspects of the present disclosure.

FIG. 5A shows an example in which trenches are etched into the chip to form the signal lines of FIG. 3A according to certain aspects of the present disclosure.

FIG. 5B shows an example in which trenches are etched into the chip to form the rails of FIG. 3A in which the trenches for the rails are deeper than the trenches for the signal lines according to certain aspects of the present disclosure.

FIG. 6A shows an example of a rail including a metal core, a liner, and a barrier according to certain aspects of the present disclosure.

FIG. 6B an example in which the barrier is not present on a bottom of the rail according to certain aspects of the present disclosure.

FIG. 7A shows a top view of another example of contacts disposed on the epi layers in the cell according to certain aspects of the present disclosure.

FIG. 7B shows an example in which a first one of the contacts is coupled to a first rail, a second one of the contacts is coupled to a second rail, and a third one of the contacts is coupled to a signal line according to certain aspects of the present disclosure.

FIG. 7C shows a cross-sectional view of the cell taken along a first cross-section line in FIG. 7B according to certain aspects of the present disclosure.

FIG. 7D shows a cross-sectional view of the cell taken along a second cross-section line in FIG. 7B according to certain aspects of the present disclosure.

FIG. 8 is a flowchart illustrating of chip fabrication according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

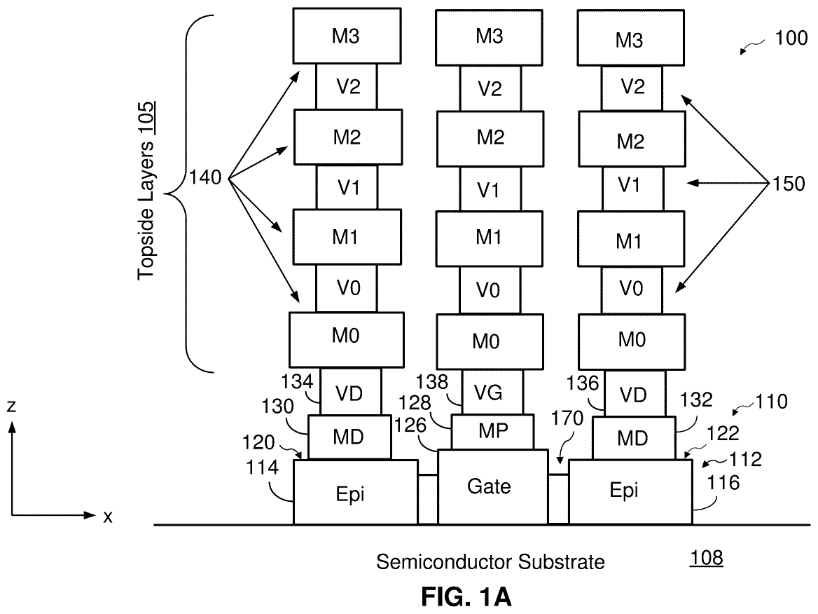

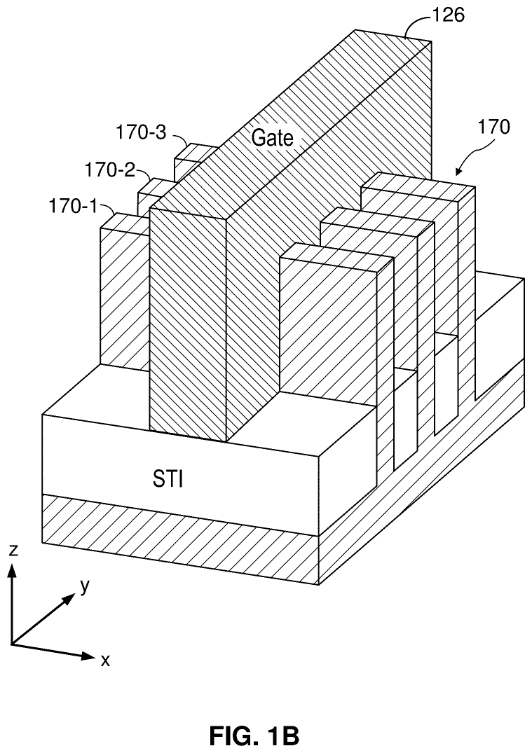

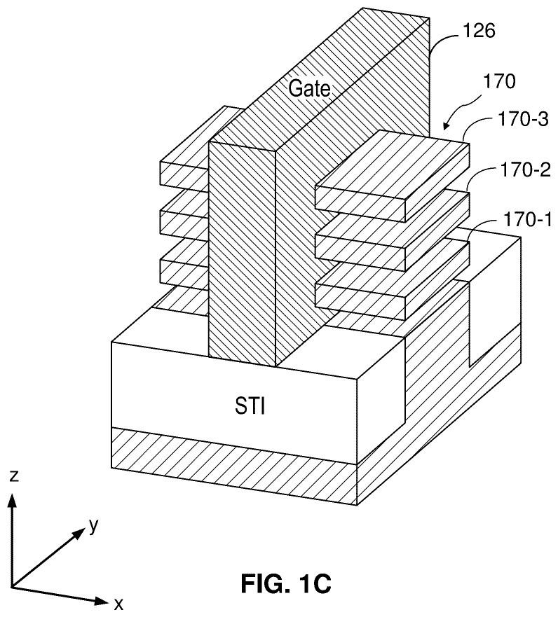

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor.

For the example of a FinFET process, the gate 126 may surround each of the one or more channels 170 on three sides. In this regard, FIG. 1B shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins. In certain aspects, the chip 100 may include shallow trench isolation (STI) to reduce leakage between devices on the chip 100. In some implementations, the STI may be omitted.

For the example of a gate-all-around FET process, the gate 126 may surround each of the one or more channels 170 (also referred as ribbons) on four sides. In this regard, FIG. 1C shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a thin spacer (not shown in FIG. 1A) between the gate 126 and each of the first epi layer 114 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail may also be referred to as a power rail or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for ease of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0.

The topside layers 105 also includes vias 150 that provide coupling between the metal layers 140. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 136 disposed between the gate contact 128 and metal layer M0, in which the via 136 couples the gate contact 128 (and hence the gate 126) to metal layer M0. For implementations where the gate contact 128 is omitted, the via 136 may be disposed between the gate 126 and metal layer M0 without an intervening gate contact. In this example, the chip 100 also includes a via 134 disposed between the contact 130 and metal layer M0, in which the via 134 couples the contact 130 to metal layer M0. The chip 100 also includes a via 136 disposed between the contact 132 and metal layer M0, in which the via 136 couples the contact 132 to metal layer M0.

Although one gate 126 is shown in FIGS. 1A to 1C, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to provide a circuit (e.g., an inverter, a driver, a logic gate, combinational logic, a latch, a flip-flop, a bit cell (e.g., a static random-access memory (SRAM) bit cell, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell.

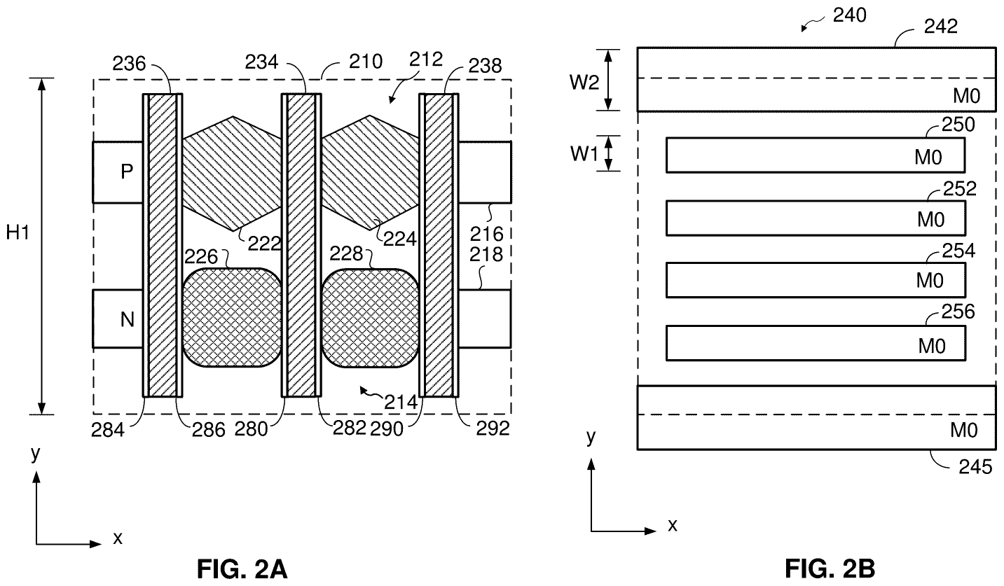

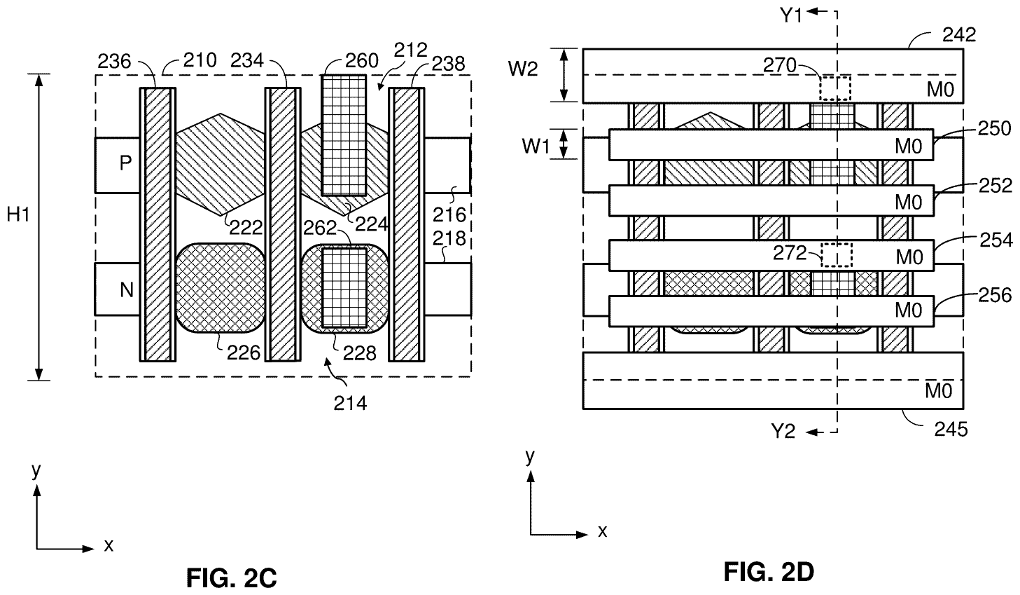

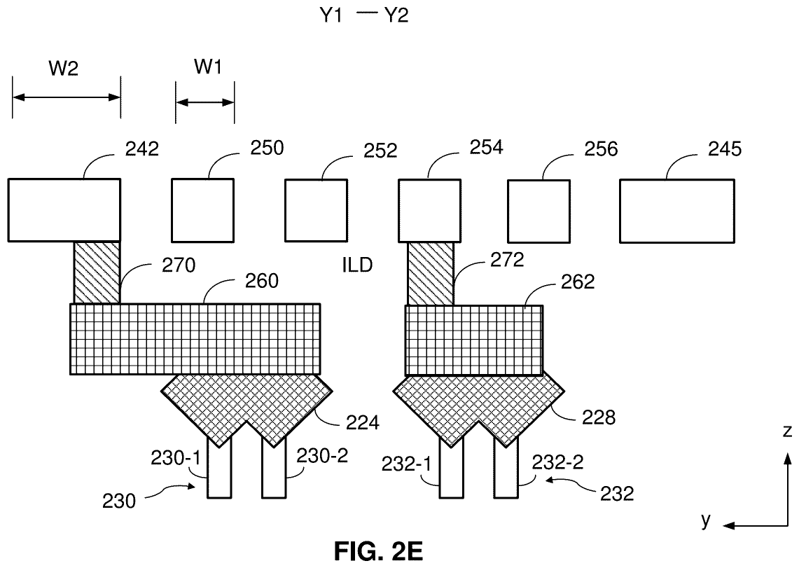

FIG. 2A shows a top view of an exemplary cell 210 integrated on the chip 100 according to certain aspects. In this example, the cell 210 includes a first diffusion region 216 extending in the x direction and a second diffusion region 218 extending in the x direction, in which the first diffusion region 216 and the second diffusion region 218 are spaced apart in the y direction. The y direction is perpendicular to the x direction and the z direction. The first diffusion region 216 includes one or more first channels 230 (shown in FIG. 2E) extending in the x direction and the second diffusion region 218 includes one or more second channels 232 (shown in FIG. 2E) extending in the x direction. In this example, the first diffusion region 216 may be a p-type diffusion region and the second diffusion region 218 may be an n-type diffusion region (e.g., to provide the cell 210 with complementary transistors). However, it is to be appreciated that the present disclosure is not limited to this example. It is also to be appreciated that the cell 210 may include more than two diffusion regions in other implementations.

The cell 210 includes a gate 234 extending in the y direction over the first diffusion region 216 and the second diffusion region 218. The gate 234 may include a metal (e.g., a high-k metal gate (HKMG)), polysilicon, and/or another gate material. For a FinFET process, the gate 126 may surround each of the one or more first channels 230 of the first diffusion region 216 on three sides, and surround each of the one or more second channels 232 of the second diffusion region 218 on three sides (e.g., as illustrated in the example in FIG. 1B). For a gate-all-around FET process, the gate 126 may surround each of the one or more first channels 230 of the first diffusion region 216 on four sides, and surround each of the one or more second channels 232 of the second diffusion region 218 on four sides (e.g., as illustrated in the example in FIG. 1C).

The first diffusion region 216 includes epitaxial (epi) layer 222 and epi layer 224, and the second diffusion region 218 includes epi layer 226 and epi layer 228. Each of the epi layers 222, 224, 226, and 228 may include epitaxially grown or deposited silicon, a silicon-based material (e.g., silicon-germanium), or any combination thereof. It is to be appreciated that the epi layers 222, 224, 226, and 228 may have shapes that are different from the exemplary shapes shown in FIG. 2A. The cell 210 also includes a thin spacer 280 disposed between the gate 234 and the epi layers 222 and 226, and a thin spacer 282 disposed between the gate and the epi layers 224 and 228. It is to be appreciated that each of the diffusion regions 216 and 218 may be represented by a rectangular shape in a mask layout of the chip 100.

The gate 234 is disposed between the epi layer 222 and the epi layer 224, in which the one or more first channels 230 pass through the gate 234 and are coupled between the epi layer 222 and the epi layer 224. The gate 234 is also disposed between the epi layer 226 and the epi layer 228, in which the one or more second channels 232 pass through the gate 234 and are coupled between the epi layer 226 and the epi layer 228. The epi layer 222 and the epi layer 226 are spaced apart in the y direction, and the epi layer 224 and the epi layer 228 are spaced apart in the y direction, as shown in FIG. 2A.

In this example, the first diffusion region 216 and the gate 234 form a first transistor 212 (e.g., a p-type field effect transistor (PFET)), in which the epi layer 222 provides a first source/drain and the epi layer 224 provides a second source/drain of the first transistor 212. The second diffusion region 218 and the gate 234 form a second transistor 214 (e.g., an n-type field effect transistor (NFET)), in which the epi layer 226 provides a first source/drain and the epi layer 228 provides a second source/drain of the second transistor 214.

In the example shown in FIG. 2A, the first transistor 212 and the second transistor 214 share the gate 234 (i.e., the gate 234 is common to both transistors 212 and 214). Two or more transistors may share a common gate in various types of cells such as an inverter cell, an SRAM cell, or another type of cell. However, it is to be appreciated that the present disclosure is not limited to this example. In other implementations, the gate 234 may be cut between the first diffusion region 216 and the second diffusion region 218 to provide separate gates for the transistors 212 and 214.

In the example illustrated in FIG. 2A, the chip 100 includes additional gates 236 and 238 spaced apart from the gate 234 in the x direction (e.g., at a uniform pitch). The additional gates 236 and 238 may be dummy gates (also known as non-functional gates). In other implementations, the transistors 212 and 214 may be multi-gate transistors, and the additional gates 236 and 238 may be additional gates of the transistors 212 and 214. In other implementations, the additional gates 236 and 238 may be replaced with diffusion breaks (e.g., single diffusion breaks or double diffusion breaks). In some implementations, the chip 100 may include spacers 284 and 286 on opposite sides of the gate 236, and spacers 290 and 292 on opposite sides of the gate 238.

FIG. 2B shows a top view of an exemplary layout of metal tracks 240 in metal layer M0. The metal tracks 240 extend in the x direction and are spaced apart from one another in the y direction. For example, the metal tracks 240 may be spaced apart in the y direction by at least a minimum spacing (i.e., pitch) defined by a design rule check (DRC) for a particular process technology. The metal tracks 240 extend over the cell 210 (not shown in FIG. 2B) to provide power and signal routing for the cell 210. In FIG. 2B, the boundary of the cell 210 is indicated by the dashed rectangle in FIG. 2B.

In this example, the metal tracks 240 include a first rail 242, a second rail 245, and signal lines 250, 252, 254, and 256. The first rail 242 may be a supply rail providing a supply voltage and the second rail 245 may be a ground rail, or vice versa. In this example, the first rail 242 overlaps the top boundary of the cell 210 and the second rail 245 overlaps the bottom boundary of the cell 210 with the signal lines 250, 252, 254, and 256 located between the first rail 242 and the second rail 245 in the y direction.

In some implementations, the first rail 242 may be shared by the cell 210 and one or more other cells located in the same row as the cell 210 and/or located in another row that is adjacent to the top boundary of the cell 210. Also, the second rail 245 may be shared by the cell 210 and one or more other cells located in the same row as the cell 210 and/or located in another row that is adjacent to the bottom boundary of the cell 210.

In the example shown in FIG. 2B, each of the signal lines 250, 252, 254, and 256 has a width of W1 and each of the rails 242 and 245 has a width of W2. As used herein, the “width” of a signal line or a rail is the dimension of the signal line or the rail in the y direction. In this example, the width W2 of each of the rails 242 and 245 is greater than the width W1 of each of the signal lines 250, 252, 254, and 256. For example, the width W2 may be at least two times wider than the width W1, but is not limited to this example. The rails 242 and 245 may be made wider in this example to reduce the resistances of the rails 242 and 245, which reduces the current-resistance (IR) drops in the rails 242 and 245.

FIG. 2C shows a top view of an example of a first contact 260 disposed on the epi layer 224 and a second contact 262 disposed on the epi layer 228. As discussed further below, the first contact 260 may be used to couple the epi layer 224 to the first rail 242 (e.g., to provide power to the cell 210), and the second contact 262 may be coupled to the signal line 254 (e.g., to provide signal routing for the cell 210). Each of the contacts 260 and 262 may be formed from a contact layer (e.g., MD layer in FIG. 1A) using lithographic and etching processes. Each of the contacts 260 and 262 may include cobalt (Co), tungsten (W), molybdenum (Mo), another conductive material, or any combination thereof.

FIG. 2D shows a top view of an example of the first rail 242, the second rail 245, and the signal lines 250, 252, 254, and 256 over the cell 210. In this example, the first contact 260 is coupled to the first rail 242 through a first via 270 (e.g., VD via in FIG. 1E) disposed between the first contact 260 and the first rail 242 in the z direction. In FIG. 2D, the first via 270 is shown in dotted line to indicate that the first via 270 is underneath the first rail 242. The first rail 242 may be a supply rail providing a supply voltage or a ground rail.

In this example, the second contact 262 is coupled to the signal line 254 through a second via 272 (e.g., VD via in FIG. 1E) disposed between the second contact 262 and the signal line 254 in the z direction. In FIG. 2D, the second via 272 is shown in dotted line to indicate that the second via 272 is underneath the signal line 254.

FIG. 2E shows a cross-sectional view taken along cross-section line Y1-Y2 in FIG. 2D. In this example, the first diffusion region 216 and the second diffusion region 218 are formed using a FinFET process in which the one or more first channels 230 include a first channel 230-1 and a second channel 230-2, and the one or more second channels 232 includes a first channel 232-1 and a second channel 232-2. In this example, each of the channels 230-1, 230-2, 232-1, and 232-2 is orientated vertically. However, it is to be appreciated that the present disclosure is not limited to this example. In other implementations, the first diffusion region 216 and the second diffusion region 218 may be formed using a gate-all-around FET process.

As shown in FIG. 2E, the rails 242 and 245 and the signal lines 250, 252, 254, and 256 have the same thickness (i.e., depth) in the z direction. In this example, the rails 242 and 245 and the signal lines 250, 252, 254, and 256 may be formed in metal layer M0 using the same lithographic, etching, and metallization processes. As shown in FIG. 2E, each of the rails 242 and 245 is wider than each of the signal lines 250, 252, 254, and 256 in the y direction.

The space between the epi layers 224 and 228 and the space between the contacts 260 and 262 and metal layer M0 may be filled with an interlayer dielectric (ILD) such as silicon dioxide (SiO2) or another dielectric material.

It is desirable to reduce the heights of cells on the chip 100 in order to fit a larger number of cells on the chip 100. For example, the height of the cell 210 (labeled “H1”) is indicated in FIG. 2A. As used herein, the “height” of a cell is the dimension of the cell in the y direction. The height of the cell 210 may be reduced by reducing the widths of the rails 242 and 245, which reduces the height of the metal tracks 240 in the y direction while maintaining the minimum spacing between the first rail 242 and the signal line 250 and the minimum spacing between the second rail 245 and the signal line 256. The reduction in the height of the metal tracks 240 allows the height of the cell 210 under the metal tracks 240 to also to be reduced. However, reducing the widths of the rails 242 and 245 increases the resistances of the rails 242 and 245, which increases the IR drops in the rails 242 and 245 and reduces the supply voltage delivered to the cell 210.

To overcome the above limitations, aspects of the present disclosure reduce the widths of the rails while making the rails taller (i.e., deeper) in the z direction. The smaller widths of the rails translate into a reduction in the cell height while making the rails taller reduces the impact of the smaller widths on the resistances of the rails. This enables cell height reduction while maintaining low rail resistance. The above features and other features of the present disclosure are discussed further below.

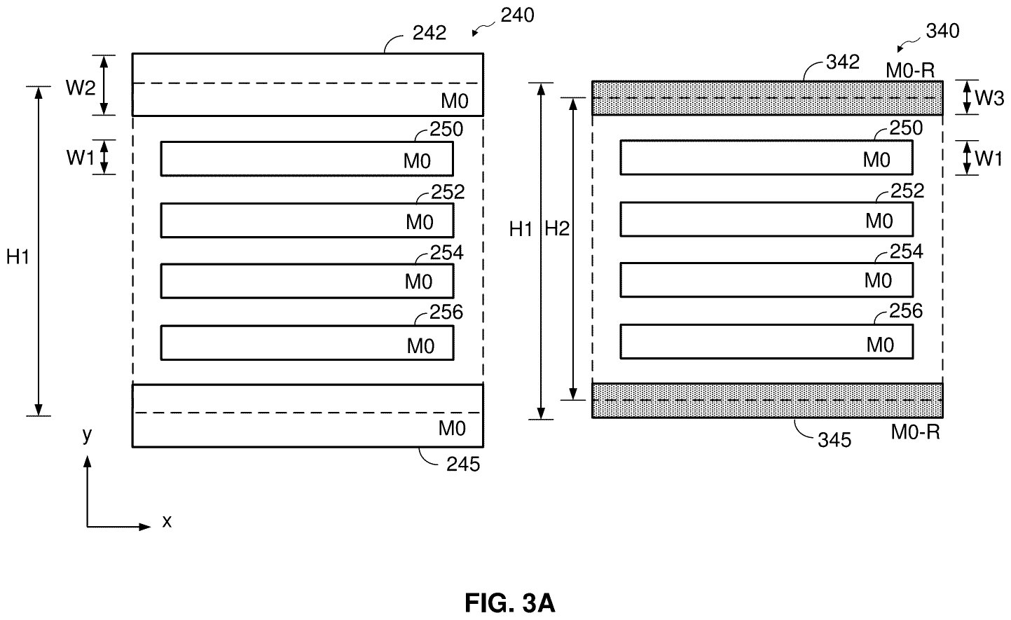

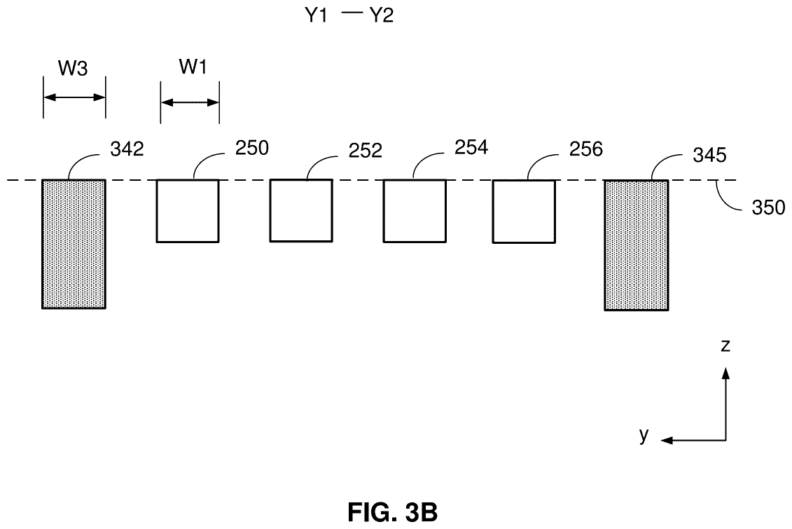

FIG. 3A shows a top view of an exemplary layout of metal tracks 340 according to certain aspects. For comparison, the metal tracks 240 in FIG. 2B are shown to the left of the metal tracks 340 for comparison.

In this example, the metal tracks 340 extend in the x direction and are spaced apart from one another in the y direction. For example, the metal tracks 340 may be spaced apart in the y direction by at least a minimum spacing (i.e., pitch) defined by a design rule check (DRC) for a particular process technology. The metal tracks 340 extend over the cell 210 (not shown in FIG. 3A) to provide power and signal routing for the cell 210. In FIG. 3A, the boundary of the cell 210 is indicated by the dashed rectangle in FIG. 3A.

In this example, the metal tracks 340 include a first rail 342, a second rail 345, and the signal lines 250, 252, 254, and 256. The first rail 342 may be a supply rail providing a supply voltage and the second rail 345 may be a ground rail, or vice versa. In this example, the first rail 342 overlaps the top boundary of the cell 210 and the second rail 345 overlaps the bottom boundary of the cell 210 with the signal lines 250, 252, 254, and 256 located between the first rail 342 and the second rail 345 in the y direction.

In some implementations, the first rail 342 may be shared by the cell 210 and one or more other cells located in the same row as the cell 210 and/or located in another row that is adjacent to the top boundary of the cell 210. Also, the second rail 345 may be shared by the cell 210 and one or more other cells located in the same row as the cell 210 and/or located in another row that is adjacent to bottom boundary of the cell 210.

In the example shown in FIG. 3A, each of the signal lines 250, 252, 254, and 256 has the width of W1 discussed above, and each of the rails 342 and 345 has a width of W3. The width W3 is smaller (i.e., narrower) that the width W2 of the rails 242 and 245 in FIG. 2B. For example, the width W3 of each of the rails 342 and 345 may be approximately equal to the width W1 of each of the signal lines 250, 252, 254, and 256 in some implementations. However, it is to be appreciated that the present disclosure is not limited to this example.

The smaller widths of the rails 342 and 345 compared with the widths of the rails 242 and 245 translates into a reduction in the height of the cell 210. In this regard, FIG. 3A shows an example in which the smaller widths of the rails 342 and 345 reduce the height of the cell 210 from H1 to H2. The cell height reduction may be between 5% to 10%, but is not limited to this example.

FIG. 3B shows a cross-sectional view of the rails 342 and 345 and the signal lines 250, 252, 254, and 256 taken along line Y1-Y2 in FIG. 3A. Each of the rails 342 and 345 is taller than each of the signal lines 250, 252, 254, and 256 in the z direction. In other words, the height of each of the rails 342 and 345 in the z direction is greater than the height of each of the signal lines 250, 252, 254, and 256 in the z direction. As discussed further below, the rails 342 and 345 may be made taller than the signal lines 250, 252, 254, and 256 by using separate lithographic processes (e.g., separate masks) and separate etching processes for the rails 342 and 345 and the signal lines 250, 252, 254, and 256. In FIGS. 3A and 3B, the rails 342 and 345 are shaded to indicate that the rails 342 and 345 and the signal lines 250, 252, 254, and 256 are defined using separate masks. In FIG. 3A, the metal layer for the rails 342 and 345 are labeled M0-R.

Comparing FIGS. 2E and 3B, the height of each of the rails 342 and 345 in the z direction is greater than the height of each of the rails 242 and 245 in the z direction. The larger height in the z direction allows each of the rails 342 and 345 to achieve a similar cross-sectional area in the y and z dimensions as each of the rails 242 and 245 with a smaller width (i.e., W3<W2). As a result, the resistance of each of the rails 342 and 345 is similar to the resistance of each of the rails 242 and 245 in this example. Thus, the larger height in the z direction allows each of the rails 342 and 345 to have a smaller width for cell height reduction while having a similar resistance as each of the rails 242 and 245.

In the example shown in FIG. 3B, the top surface of each of the rails 342 and 345 is aligned with the top surface of each of the signal lines 250, 252, 254, and 256 in the z direction. This is shown in FIG. 3B by the line 350 extending in the y direction in which the top surfaces of the rails 342 and 345 and the top surfaces of the signal lines 250, 252, 254, and 256 are aligned (i.e., flush) with the line 350 in the z direction. Because the top surfaces of the rails 342 and 345 are aligned with the top surfaces of the signal lines 250, 252, 254, and 256, the rails 342 and 345 do not interfere with signal routing in metal layer M1 (e.g., one or more signal lines in metal layer M1 may pass over the first rail 342 and/or the second rail 345).

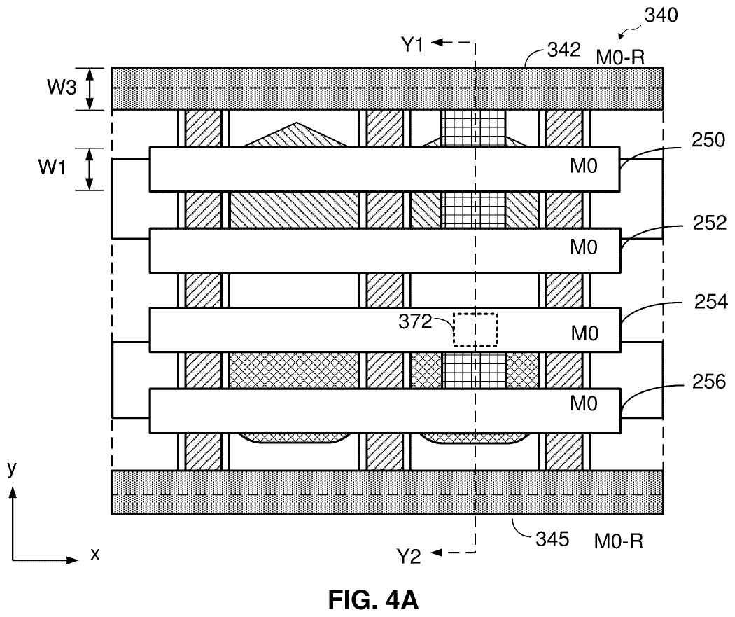

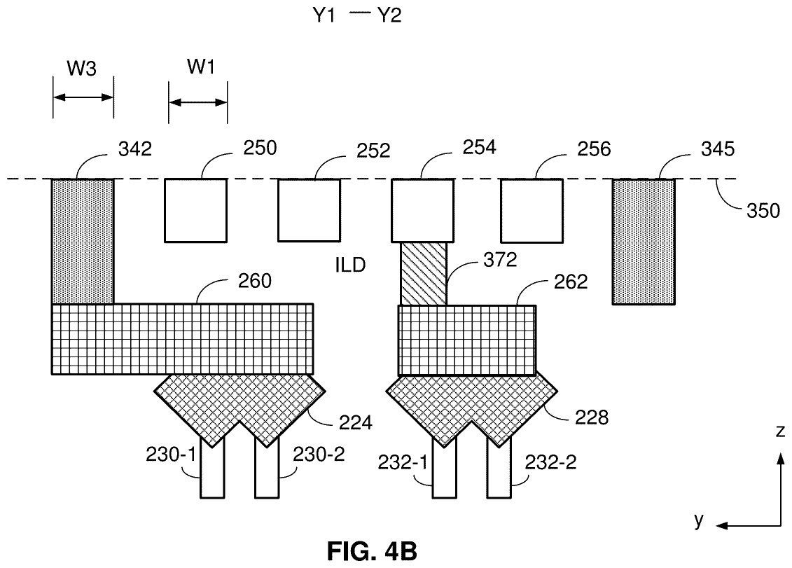

FIG. 4A shows a top view of an example of the first rail 342, the second rail 345, and the signal lines 250, 252, 254, and 256 over the cell 210. In this example, the first contact 260 is coupled to the first rail 342 without the first via 270 (e.g., VD via) shown in FIG. 2D. As discussed further below, this is because the first rail 342 extends down to the first contact 260. The first rail 342 may be a supply rail providing the cell 210 with a supply voltage or a ground rail.

In this example, the second contact 262 is coupled to the signal line 254 through a via 372 (e.g., VD via in FIG. 1E) disposed between the second contact 262 and the signal line 254 in the z direction. In FIG. 4A, the via 372 is shown in dotted line to indicate that the via 372 is underneath the signal line 254. The vias 372 may be the same as the second via 272 shown in FIG. 2D.

FIG. 4B shows a cross-sectional view taken along cross-section line Y1-Y2 in FIG. 4A. In this example, the first diffusion region 216 and the second diffusion region 218 are formed using the FinFET process discussed above in which the one or more first channels 230 include the first channel 230-1 and the second channel 230-2, and the one or more second channels 232 include the first channel 232-1 and the second channel 232-2. In this example, each of the channels 230-1, 230-2, 232-1, and 232-2 is orientated vertically. However, it is to be appreciated that the present disclosure is not limited to this example. In other implementations, the first diffusion region 216 and the second diffusion region 218 may be formed using a gate-all-around FET process. In other words, aspects of the present disclosure may be used for FinFet or gate-all-around FET based technologies.

As discussed above, each of the rails 342 and 345 is taller than each of the signal lines 250, 252, 254, and 256 in the z direction (i.e., the height of each of the rails 342 and 345 in the z direction is greater than the height of each of the signal lines 250, 252, 254, and 256 in the z direction). In the example shown in FIG. 4B, the larger height of the rails 342 and 345 allows the first rail 342 to extend downward to a greater depth than the signal lines 250, 252, 254, and 256 and make electrical contact with the first contact 260 without the intervening via 270 shown in FIG. 2E, which reduces interface resistance. Thus, in this example, the VD vias for the rails may be eliminated, which may lower yield loss due to VD process issues such as VD open and VD to neighboring MD/M0 shorts.

In the example shown in FIG. 4B, the height of the first rail 342 in the z direction is approximately equal to the sum of the height of the signal line 254 in the z direction and the height of the via 372 in the z direction. This allows the first rail 342 to make electrical contact with the first contact 260 without the via 270 shown in FIG. 2E. However, it is to be appreciated that the present disclosure is not limited to this example.

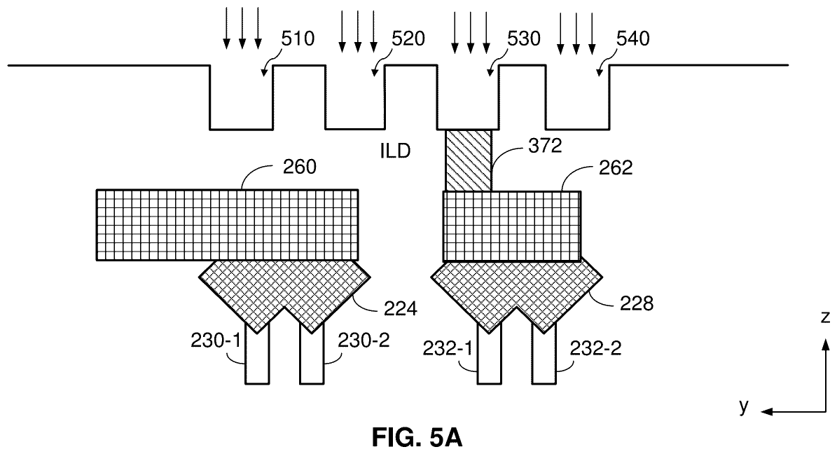

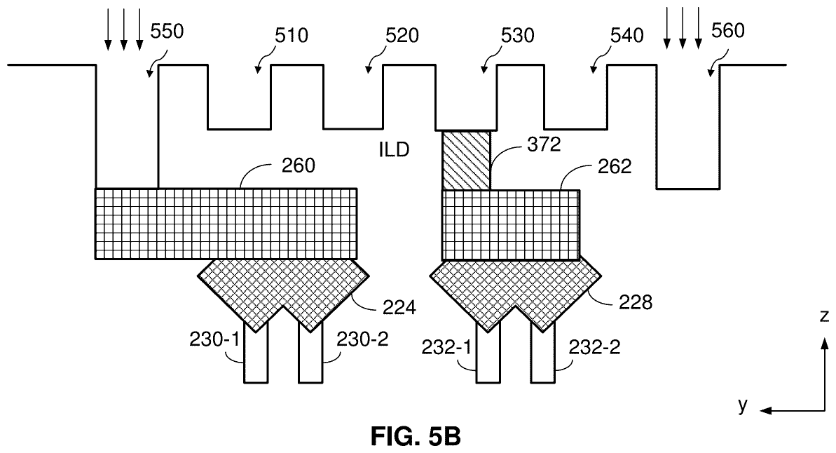

As discussed above the rails 342 and 345 and the signal lines 250, 252, 254, and 256 may be formed using separate lithographic processes and separate etching processes. In this regard, FIG. 5A illustrates an example of a lithographic and etching process for etching trenches for the signal lines 250, 252, 254, and 256, and FIG. 5B illustrates an example of a lithographic and etching process for etching trenches for the rails 342 and 345. As discussed further below, the separate lithographic processes and separate etching processes for the rails 342 and 345 and the signal lines 250, 252, 254, and 256 allow the trenches for the rails 342 and 345 to be etched to a greater depth than the trenches for the signal lines 250, 252, 254, and 256, which allows the rails 342 and 345 to be taller than the signal lines 250, 252, 254, and 256.

FIG. 5A shows a cross-sectional view taken along cross-section line Y1-Y2 in which trenches 510, 520, 530, and 540 are etched into the ILD for the signal lines 250, 252, 254, and 256 during a first etching process. The areas of the ILD that are etched during the first etching process are defined by a first lithographic process (e.g., using dual mask extreme ultraviolet (EUV) lithography or another type of lithography).

The first etching process may include a reactive ion etching process, a plasma etching process, and/or another type of suitable etching process. In FIG. 5A, the direction of the etching is indicated by the arrows pointing into the openings of the trenches 510, 520, 530, and 540. In the example in FIG. 5A, the first etching process etches the ILD to the depth of the via 372 to form the trench 530 for signal line 254.

FIG. 5B shows a cross-sectional view taken along cross-section line Y1-Y2 in which a first trench 550 and a second trench 560 are etched into the ILD for the first rail 342 and the second rail 345, respectively, during a second etching process. The areas of the ILD that are etched during the second etching process are defined by a second lithographic process (e.g., using immersion lithography or another type of lithography).

The second etching process may include a reactive ion etching process, a plasma etching process, and/or another type of suitable etching process. In FIG. 5B, the direction of the etching is indicated by the arrows pointing into the openings of the trenches 550 and 560. In the example in FIG. 5B, the second etching process etches the ILD to the depth of the first contact 260 to form the first trench 550.

As shown in FIG. 5B, the second etching process etches the ILD at a greater depth than the first etching process. As a result, the trenches 550 and 560 for the rails 342 and 345 are deeper than the trenches 510, 520, 530, and 540 for the signal lines 250, 252, 254, and 256. This allows the rails 342 and 345 to be taller than the signal lines 250, 252, 254, and 256.

It is to be appreciated that the second etching process may be performed before the first etching process in some implementations. In other words, the present disclosure is not limited to a particular order for the first etching process and the second etching process.

After the trenches 510, 520, 530, 540, 550, and 560 are formed, the trenches 510, 520, 530, 540, 550, and 560 may be filled with one or more metals to form the signal lines 250, 252, 254, and 256 and the rails 342 and 345. For example, the trenches 510, 520, 530, 540, 550, and 560 may be filled with the one or more metals in the same metallization process or separate metallization processes.

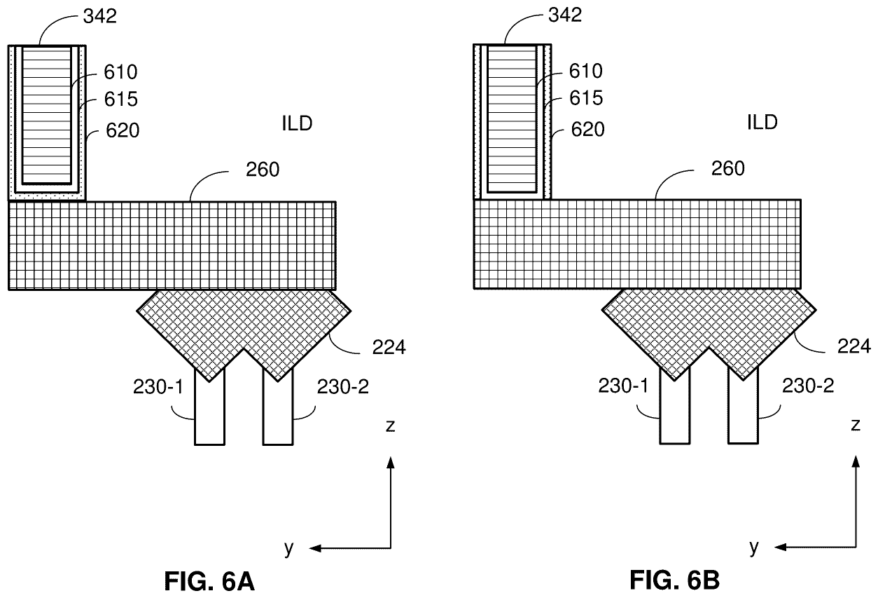

FIG. 6A shows an example in which the first rail 342 includes a metal core 610, a liner 615, and a barrier 620. In this example, the liner 615 surrounds the metal core 610 and the barrier 620 surrounds the liner 615. The barrier 620 may be used to prevent the metal (e.g., copper) in the metal core 610 from diffusing into the ILD. In this regard, the barrier 620 may also be referred to as a diffusion barrier. The liner 615 may be used to help adhere the barrier 620 to the metal core 610. The liner 615 may include cobalt, ruthenium, and/or another material, and the barrier 620 may include tantalum and/or another material. The second rail 345 and each of the signal lines 250, 252, 254, and 256 may also include a metal core, a liner, and a barrier.

FIG. 6B shows another example of the first rail 342 in which the the barrier 620 is not present on the bottom of the first rail 342. This allows the first rail 342 to make contact with the first contact 260 without the barrier 620 disposed between the metal core 610 and the first contact 260, which may reduce the resistance between the metal core 610 and the contact 260. In this example, the barrier 620 is not needed between the metal core 610 and the first contact 260 since the first contact 260 is not made of a dielectric material. The barrier 620 is present on the sidewalls of the first rail 342 to provide a barrier between the metal core 610 and the ILD. In this example, the barrier 620 may be formed using a reverse selective barrier (RSB) process that deposits the barrier material on the sidewalls of the trench 550 for the first rail 342, but does not deposit the barrier material on the bottom of the trench 550.

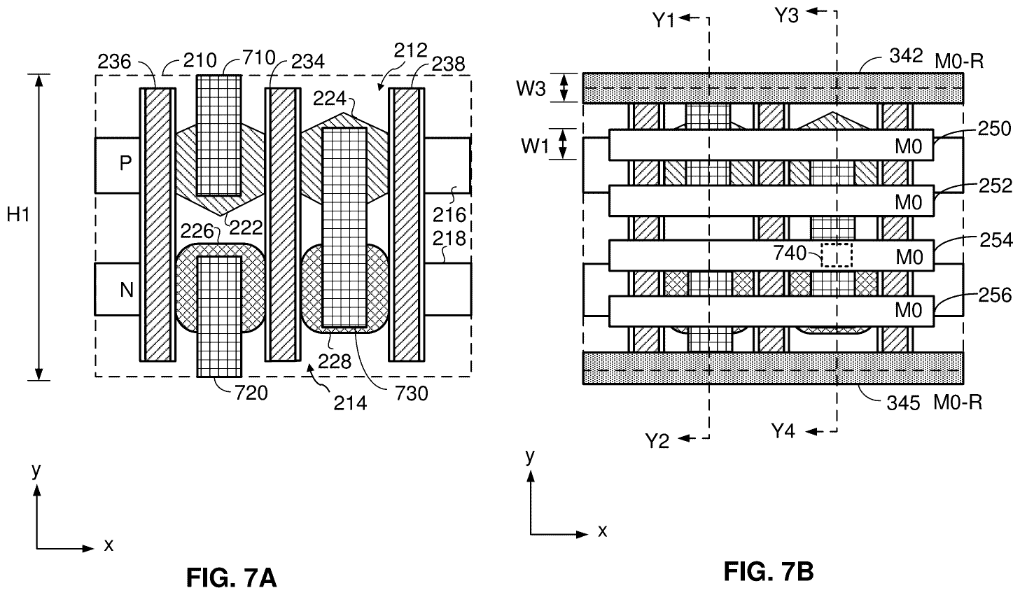

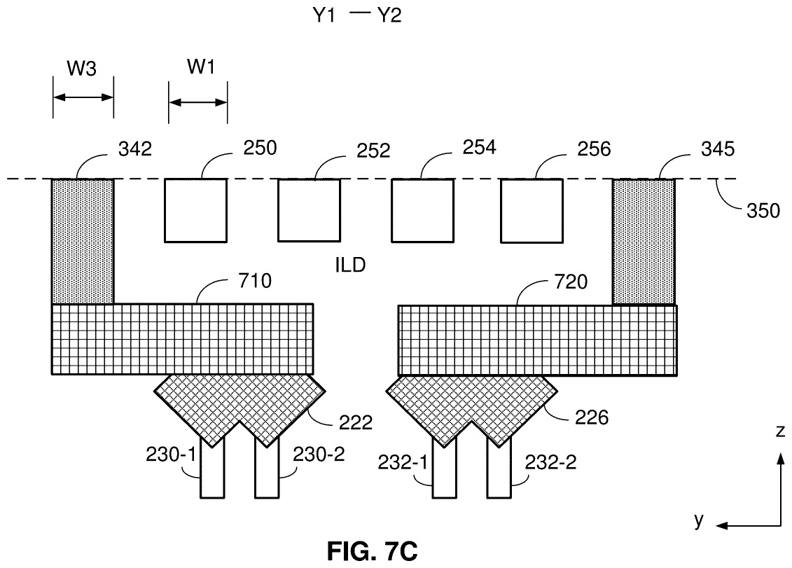

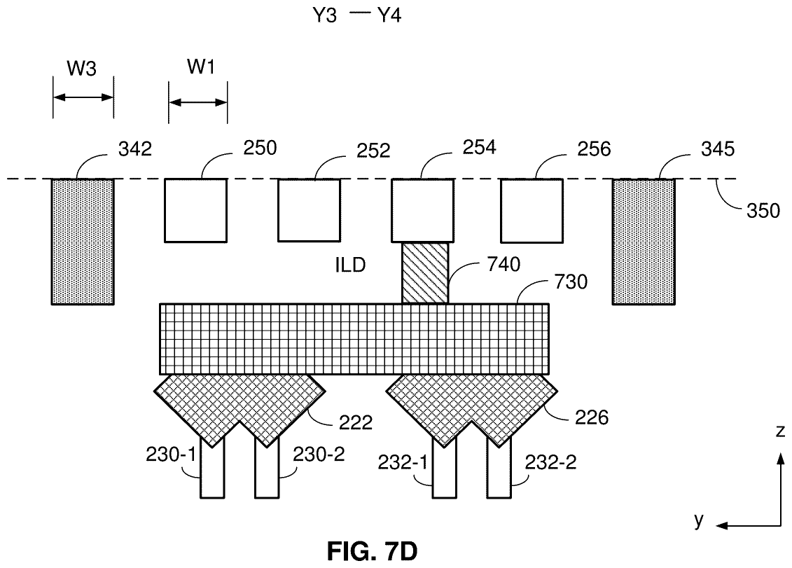

FIG. 7A shows a top view of another example of contacts for the cell 210 according to certain aspects. In this example, the contacts include a first contact 710 disposed on the epi layer 222, a second contact 720 disposed on the epi layer 226, and a third contact 730 disposed on the epi layers 224 and 228. As discussed further below, the first contact 710 may be used to couple the epi layer 222 to the first rail 342 (e.g., power rail), the second contact 720 may be used to couple the epi layer 226 to the second rail 345 (e.g., ground rail), and the third contact 730 may be used to couple the epi layers 224 and 228 to the signal line 254 (e.g., to provide signal routing for the cell 210). Each of the contacts 710, 720, and 730 may be formed from a contact layer (e.g., MD layer in FIG. 1A) using lithographic and etching processes. In this example, the contacts 710, 720, and 730 may be used to couple the transistors 212 and 214 in the cell 210 to form a complementary inverter, in which the third contact 730 provides the output of the inverter. The input of the inverter may be coupled to the gate 234. However, it is to be appreciated that the present disclosure is not limited to this example, and that the transistors 212 and 214 may be coupled to form other types of logic gates or circuits.

FIG. 7B shows a top view of an example of the first rail 342, the second rail 345, and the signal lines 250, 252, 254, and 256 over the cell 210 of FIG. 7A. In this example, the first contact 710 is coupled to the first rail 342 and the second contact 720 is coupled to the second rail 345. Also, in this example, the third contact 730 is coupled to the signal line 254 through a via 740 (e.g., VD via in FIG. 1E) disposed between the third contact 730 and the signal line 254 in the z direction. In FIG. 7B, the via 740 is shown in dotted line to indicate that the via 740 is underneath the signal line 254.

FIG. 7C shows a cross-sectional view taken along cross-section line Y1-Y2 in FIG. 7B. In this example, the first diffusion region 216 and the second diffusion region 218 are formed using the FinFET process discussed above in which the one or more first channels 230 include the first channel 230-1 and the second channel 230-2, and the one or more second channels 232 includes the first channel 232-1 and the second channel 232-2. In this example, each of the channels 230-1, 230-2, 232-1, and 232-2 is orientated vertically. However, it is to be appreciated that the present disclosure is not limited to this example. In other implementations, the first diffusion region 216 and the second diffusion region 218 may be formed using a gate-all-around FET process. In other words, aspects of the present disclosure may be used for FinFet or gate-all-around FET based technologies.

As discussed above, each of the rails 342 and 345 is taller than each of the signal lines 250, 252, 254, and 256 in the z direction. In the example shown in FIG. 7C, the larger height of the rails 342 and 345 allows the first rail 342 and the second rail 345 to extend downward to a greater depth than the signal lines 250, 252, 254, and 256 and make electrical contact with the first contact 710 and the second contact 720, respectively. In this example, the first contact 710 extends in the y direction to couple the epi layer 222 to the first rail 342, and the second contact 720 extends in the y direction to couple the epi layer 226 to the second rail 345.

FIG. 7D shows a cross-sectional view taken along cross-section line Y3-Y4 in FIG. 7B. In this example, the via 740 is disposed between the signal line 254 and the third contact 730 to couple the third contact 730 to the signal line 254. In the example shown in FIG. 7D, the height of each of the rails 342 and 345 in the z direction is approximately equal to the sum of the height of the signal line 254 in the z direction and the height of the via 740 in the z direction.

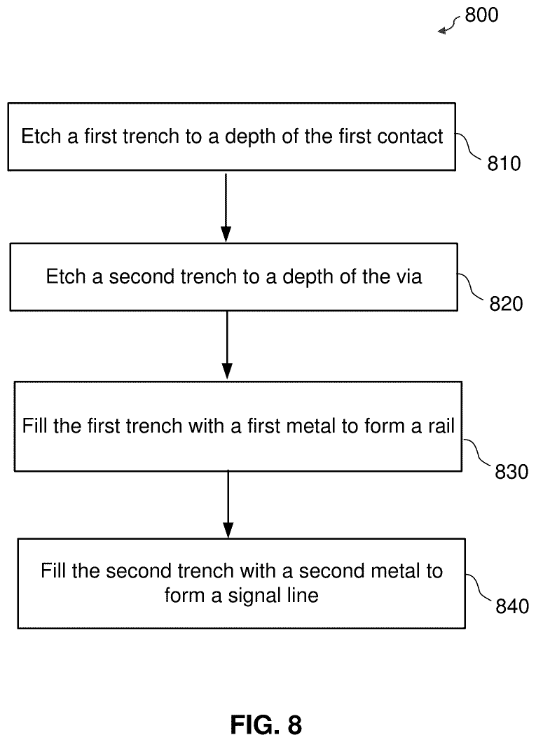

FIG. 8 illustrates a method 800 for fabricating a chip according to certain aspects. The chip includes a first epitaxial (epi) layer (e.g., epi layer 224), a first contact (e.g., first contact 260) disposed on the first epi layer, a second epi layer (e.g., epi layer 228), a second contact (e.g., 262) disposed on the second epi layer, a via (e.g., via 372) disposed on the second contact, and a dielectric layer (e.g., the ILD) over the first contact and the via.

At block 810, a first trench is etched in the dielectric layer to a depth of the first contact. For example, the first trench may correspond to the trench 550.

At block 820, a second trench is etched in the dielectric layer to a depth of the via. For example, the second trench may correspond to the trench 530. In certain aspects, the first trench and the second trench are etched in separate etching processes. In certain aspects, the second trench may be etched before the first trench. In other words, the method 800 is not limited to a particular order for the etching of the first trench and the etching of the second trench.

At block 830, the first trench is filled with a first metal to form a rail. For example, the rail may correspond to the first rail 342. The rail may be a supply rail or a ground rail.

At block 840, the second trench is filled with a second metal to form a signal line. For example, the signal line may correspond to the signal line 254. In certain aspects, the first trench and the second trench may be filled with metal in the same metallization process or separate metallization processes. For the same metallization process, the first trench and the second trench may be filled with metal concurrently. For separate metallization processes, the first trench and the second trench may be filled with metal in either order.

In certain aspects, the first metal and the second metal may be the same type of metal and may be deposited into the respective trenches in the same metallization process. However, it is to be appreciated that the present disclosure is not limited to this example.

In certain aspects, the first trench has a first height in a first direction (e.g., z direction), the second trench has a second height in the first direction, and the first height is greater than the second height.

In certain aspects, the first height is approximately equal to a sum of the second height and a height of the via in the first direction.

In certain aspects, the first trench has a first width (e.g., W3) in a second direction (e.g., y direction) perpendicular to the first direction, the second trench has a second width (e.g., W1) in the second direction, and the first width is approximately equal to the second width.

Implementation examples are described in the following numbered clauses:
1. A chip, comprising:
   a first epitaxial (epi) layer;
   a first contact disposed on the first epi layer;
   a rail coupled to the first contact, wherein the rail has a first height in a first direction;
   a second epi layer;
   a second contact disposed on the second epi layer;
   a signal line, wherein the signal line has a second height in the first direction, and
   the first height is greater than the second height; and
   a via disposed between the second contact and the signal line in the first direction.
2. The chip of clause 1, wherein the first height is approximately equal to a sum of the second height and a height of the via in the first direction.
3. The chip of clause 1 or 2, wherein a top surface of the rail is aligned with a top surface of the signal line in the first direction.
4. The chip of any one of clauses 1 to 3, wherein the rail extends in a second direction perpendicular to the first direction.
5. The chip of clause 4, wherein the rail has a first width in a third direction perpendicular to the first direction and the second direction, the signal line has a second width in the third direction, and the first width is approximately equal to the second width.
6. The chip of clause 5, wherein the signal line extends in the second direction.
7. The chip of any one of clauses 1 to 6, further comprising:
   one or more first channels coupled to the first epi layer; and
   one or more second channels coupled to the second epi layer.
8. The chip of any one of clauses 1 to 7, wherein the rail comprises a supply rail.
9. The chip of any one of clauses 1 to 7, wherein the rail comprises a ground rail.
10. The chip of any one of clauses 1 to 9, wherein the rail comprises:
   a metal core;
   a barrier; and
   a liner disposed between a sidewall of the metal core and a sidewall of the barrier, and disposed between the metal core and the first contact.
11. A chip, comprising:
   a first rail;
   a second rail, wherein each of the first rail and the second rail has a first height in a first direction;
   a first epitaxial (epi) layer;
   a first contact disposed on the first epi layer, wherein the first rail is coupled to the first contact;
   signal lines between the first rail and the second rail in a second direction perpendicular to the first direction, wherein each of the signal lines has a second height in the first direction, and the first height is greater than the second height;
   a second epi layer;
   a second contact disposed on the second epi layer; and
   a via disposed between the second contact and one of the signal lines in the first direction.
12. The chip of clause 11, wherein the first height is approximately equal to a sum of the second height and a height of the via in the first direction.
13. The chip of clause 11 or 12, wherein a top surface of each the first rail and the second rail is aligned with a top surface of each of the signal lines in the first direction.
14. The chip of any one of clauses 11 to 13, wherein each of the first rail and the second rail has a first width in the second direction, each of the signal lines has a second width in the second direction, and the first width is approximately equal to the second width.
15. The chip of any on clauses 11 to 14, wherein the first rail comprises a supply rail and the second rail comprises ground rail.
16. The chip of any one of clauses 11 to 15, wherein the first rail comprises:
   a metal core;
   a barrier; and
   a liner disposed between a sidewall of the metal core and a sidewall of the barrier, and disposed between the metal core and the first contact.
17. A method for fabricating a chip, wherein the chip includes a first epitaxial (epi) layer, a first contact disposed on the first epi layer, a second epi layer, a second contact disposed on the second epi layer, a via disposed on the second contact, and a dielectric layer over the first contact and the via, the method comprising:
   etching a first trench in the dielectric layer to a depth of the first contact;
   etching a second trench in the dielectric layer to a depth of the via;
   filling the first trench with a first metal to form a rail; and
   filling the second trench with a second metal to form a signal line.
18. The method of clause 17, wherein the first trench has a first height in a first direction, the second trench has a second height in the first direction, and the first height is greater than the second height.
19. The method of clause 18, wherein the first height is approximately equal to a sum of the second height and a height of the via in the first direction.
20. The method of clause 19, wherein the first trench has a first width in a second direction perpendicular to the first direction, the second trench has a second width in the second direction, and the first width is approximately equal to the second width.
21. A chip, comprising:
   a first rail;
   a second rail, wherein each of the first rail and the second rail has a first height in a first direction;
   a first epitaxial (epi) layer;
   a first contact disposed on the first epi layer, wherein the first rail is coupled to the first contact;
   a second epi layer;
   a second contact disposed on the second epi layer, wherein the second rail is coupled to the second contact;
   signal lines between the first rail and the second rail in a second direction perpendicular to the first direction, wherein each of the signal lines has a second height in the first direction, and the first height is greater than the second height;
   a third epi layer;
   a third contact disposed on the third epi layer; and
   a via disposed between the third contact and one of the signal lines in the first direction.
22. The chip of clause 21, further comprising a gate extending in the second direction, wherein the gate is disposed between the first epi layer and the third epi layer.
23. The chip of clause 22, further comprising one or more first channels coupled to the first epi layer and the third epi layer, wherein the one or more first channels pass through the gate.
24. The chip of clause 23, further comprising a fourth epi layer, wherein the third contact is disposed on the fourth epi layer, and the gate is disposed between the second epi layer and the fourth epi layer.
25. The chip of clause 24, further comprising one or more second channels coupled to the second epi layer and the fourth epi layer, wherein the one or more second channels pass through the gate.
26. The chip of any one of clauses 21 to 25, wherein the first height is approximately equal to a sum of the second height and a height of the via in the first direction.
27. The chip of any one of clauses 21 to 26, wherein a top surface of each the first rail and the second rail is aligned with a top surface of each of the signal lines in the first direction.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first epitaxial (epi) layer;
a first contact disposed on the first epi layer;
a rail coupled to the first contact, wherein the rail has a first height in a first direction;
a second epi layer;
a second contact disposed on the second epi layer;
a signal line, wherein the signal line has a second height in the first direction, and the first height is greater than the second height; and
a via disposed between the second contact and the signal line in the first direction.

2. The chip of claim 1, wherein the first height is approximately equal to a sum of the second height and a height of the via in the first direction.

3. The chip of claim 1, wherein a top surface of the rail is aligned with a top surface of the signal line in the first direction.

4. The chip of claim 1, wherein the rail extends in a second direction perpendicular to the first direction.

5. The chip of claim 4, wherein the rail has a first width in a third direction perpendicular to the first direction and the second direction, the signal line has a second width in the third direction, and the first width is approximately equal to the second width.

6. The chip of claim 5, wherein the signal line extends in the second direction.

7. The chip of claim 1, further comprising:
one or more first channels coupled to the first epi layer; and
one or more second channels coupled to the second epi layer.

8. The chip of claim 1, wherein the rail comprises a supply rail.

9. The chip of claim 1, wherein the rail comprises a ground rail.

10. The chip of claim 1, wherein the rail comprises:
a metal core;
a barrier; and
a liner disposed between a sidewall of the metal core and a sidewall of the barrier, and disposed between the metal core and the first contact.

11. A chip, comprising:
a first rail;
a second rail, wherein each of the first rail and the second rail has a first height in a first direction;
a first epitaxial (epi) layer;
a first contact disposed on the first epi layer, wherein the first rail is coupled to the first contact;
signal lines between the first rail and the second rail in a second direction perpendicular to the first direction, wherein each of the signal lines has a second height in the first direction, and the first height is greater than the second height;
a second epi layer;
a second contact disposed on the second epi layer; and
a via disposed between the second contact and one of the signal lines in the first direction.

12. The chip of claim 11, wherein the first height is approximately equal to a sum of the second height and a height of the via in the first direction.

13. The chip of claim 11, wherein a top surface of each the first rail and the second rail is aligned with a top surface of each of the signal lines in the first direction.

14. The chip of claim 11, wherein each of the first rail and the second rail has a first width in the second direction, each of the signal lines has a second width in the second direction, and the first width is approximately equal to the second width.

15. The chip of claim 11, wherein the first rail comprises a supply rail and the second rail comprises ground rail.

16. The chip of claim 11, wherein the first rail comprises:
a metal core;
a barrier; and
a liner disposed between a sidewall of the metal core and a sidewall of the barrier, and disposed between the metal core and the first contact.

17. A method for fabricating a chip, wherein the chip includes a first epitaxial (epi) layer, a first contact disposed on the first epi layer, a second epi layer, a second contact disposed on the second epi layer, a via disposed on the second contact, and a dielectric layer over the first contact and the via, the method comprising:
etching a first trench in the dielectric layer to a depth of the first contact;
etching a second trench in the dielectric layer to a depth of the via;
filling the first trench with a first metal to form a rail; and
filling the second trench with a second metal to form a signal line.

18. The method of claim 17, wherein the first trench has a first height in a first direction, the second trench has a second height in the first direction, and the first height is greater than the second height.

19. The method of claim 18, wherein the first height is approximately equal to a sum of the second height and a height of the via in the first direction.

20. The method of claim 19, wherein the first trench has a first width in a second direction perpendicular to the first direction, the second trench has a second width in the second direction, and the first width is approximately equal to the second width.
